(19) United States
(12) Patent Application Publication
(10) Pub. No.: US 2005/0142746 A1
(43) Pub. Date: Jun. 30, 2005

(54) Method of fabricating flash memory device

(75) Inventors: Sung Mun Jung, Yeoju-gun (KR); Jum Soo Kim, Icheon (KR)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignee: DongbuAnam Semiconductor Inc.

(21) Appl. No.: 11/019,315

(22) Filed: Dec. 23, 2004

(30) Foreign Application Priority Data
Dec. 27, 2003 (KR) P 2003-0098363

(51) Int. Cl. H01L 21/336

(52) U.S. Cl. 438/257; 438/264

(57) ABSTRACT

The present invention provides a method of fabricating a flash memory device, by which a coupling ratio is raised in a manner of shortening an interval between floating gates using a spacer and by which a bridge generation is avoided between control and floating gates. The present invention includes forming a trench isolation layer defining an active area of a semiconductor substrate, forming a tunnel oxide layer on the active area, forming a first conductor layer for a floating gate over the substrate, forming an insulating layer pattern on the first conductor layer with a prescribed layer having high etch selectivity with the trench isolation layer to expose a portion of the first conductor layer, forming a spacer on a sidewall of the insulating layer pattern, forming a first conductor layer pattern exposing a portion of the trench isolation layer by removing the exposed portion of the first conductor layer using the spacer as an etch mask, removing the insulating layer pattern and the spacer, forming a gate-to-gate insulating layer over the substrate, and forming a second conductor layer on the gate-to-gate insulating layer.

This application claims the benefit of the Korean Application No. P2003-0098363 filed on Dec. 27, 2003, which is hereby incorporated by reference.

### BACKGROUND OF THE INVENTION

1. Field of the Invention

The present invention relates to a method of fabricating a flash memory device, and more particularly, to a method of fabricating a flash memory device having trench isolation.

2. Discussion of the Related Art

Generally, a coupling ratio between floating and control gates should be uniformly maintained for program and erase operations of a flash memory device. As the tendency of a semiconductor device toward high integration and reduced size rises, a flash memory device decreases in size as well. Hence, a coupling ratio is lowered to degrade the program and erase efficiencies of the flash memory device. In one of many methods having been proposed to overcome such a problem, an interval between floating gates is shortened using a spacer, which is disclosed in Korean Patent Application Laid Open No. 2001-0065230.

FIGS. 1 to 3 are cross-sectional diagrams for explaining a method of fabricating a flash memory device according to a related art.

Referring to FIG. 1, a trench 120 is formed on a device isolation area of a semiconductor substrate 100 by trench isolation.

And, the trench 120 is filed up with a filling oxide layer 130 to form a trench isolation layer 130.

Subsequently, a tunnel oxide layer 140 is formed on an active area 110 of the semiconductor substrate 100 defined by the trench isolation layer.

A first conductor layer 150 for forming a floating gate is formed on the trench isolation layer 130 and the tunnel oxide layer 140.

An insulating layer pattern 160 is formed on the first conductor layer 150 to expose a portion of the first conductor layer 150. The insulating layer pattern 160 can be formed by photolithography.

A spacer insulating layer 170 is then formed on the insulating layer pattern 160 and the exposed portion of the first conductor layer 150.

Referring to FIG. 2, the spacer insulating layer 170 is anisotropically etched to form a spacer 175 on a sidewall of the insulating layer pattern 160.

And, the exposed portion of the first conductor layer 150 is etched using the spacer 175 and the insulating layer pattern 160 as an etch mask. Hence, a first conductor layer pattern 155 exposing a portion of the trench isolation layer 130 is formed. And, the first conductor layer pattern 155 will be used as a floating gate.

Referring to FIG. 3, the insulating layer pattern 160 in FIG. 2 and the spacer 175 are removed prior to forming a gate-to-gate insulating layer and a control gate.

Subsequently, a gate-to-gate insulating layer 180 is formed over the semiconductor substrate 100.

And, a second conductor layer 190 is formed as a control gate on the gate-to-gate insulating layer.

In the related art method, the trench isolation layer 130 is formed of high density plasma oxide and the insulating layer pattern 160 and the spacer 175 are formed of TEOS oxide. Hence, while the insulating layer pattern 160 and the spacer 175 are removed, an upper part of the trench isolation layer 130 is simultaneously removed to generate undercut.

However, if the gate-to-gate insulating layer 180 and the second conductor layer 190 are formed under the undercut situation, a residue generation is inevitable along the area where the undercut is generated.

The residue is not removed quite well due to the interruption of the gate-to-gate insulating layer 180 but to remain in separating the second conductor layer 190.

Hence, the residue brings about a bridge phenomenon short-circuiting the floating gate and the control gate.

### SUMMARY OF THE INVENTION

Accordingly, the present invention is directed to a method of fabricating a flash memory device that substantially obviates one or more problems due to limitations and disadvantages of the related art.

An object of the present invention is to provide a method of fabricating a flash memory device, by which a coupling ratio is raised in a manner of shortening an interval between floating gates using a spacer and by which a bridge generation is avoided between control and floating gates.

Additional advantages, objects, and features of the invention will be set forth in part in the description which follows and in part will become apparent to those having ordinary skill in the art upon examination of the following or may be learned from practice of the invention. The objectives and other advantages of the invention may be realized and attained by the structure particularly pointed out in the written description and claims hereof as well as the appended drawings.

To achieve these objects and other advantages and in accordance with the purpose of the invention, as embodied and broadly described herein, a method of fabricating a flash memory device according to the present invention includes the steps of forming a trench isolation layer defining an active area of a semiconductor substrate, forming a tunnel oxide layer on the active area of the semiconductor substrate, forming a first conductor layer for a floating gate on the tunnel oxide layer and the trench isolation layer, forming an insulating layer pattern on the first conductor layer with a prescribed layer having high etch selectivity with the trench isolation layer to expose a portion of the first conductor layer, forming a spacer on a sidewall of the insulating layer pattern, forming a first conductor layer pattern exposing a portion of the trench isolation layer by removing the exposed portion of the first conductor layer using the spacer as an etch mask, removing the insulating layer pattern and the spacer, forming a gate-to-gate insulating layer on the first conductor layer pattern and the trench isolation layer, and forming a second conductor layer for a control gate on the gate-to-gate insulating layer.

Preferably, the trench isolation layer is formed of high density plasma oxide and both of the insulating layer pattern and the spacer are formed of plasma nitride.

More preferably, the plasma nitride is deposited at 350˜600° C.

Preferably, the insulating layer pattern and the spacer are removed by wet etch using a H₃PO₄ solution as an etchant.

Preferably, the etch selectivity between the insulating pattern and the trench isolation layer is 70˜150:1.

Preferably, both of the first and second conductor layers are formed of polysilicon and the gate-to-gate insulating layer is formed of an oxide/nitride/oxide layer.

Preferably, the method further includes the step of forming a buffer layer on the first conductor layer prior to forming the insulating layer pattern.

More preferably, the buffer layer is formed of an oxide layer 50˜500 Å thick.

Preferably, the buffer layer is formed of one selected from the group consisting of PSG, BPSG, and TEOS.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention. In the drawings:

FIGS. 1 to 3 are cross-sectional diagrams for explaining a method of fabricating a flash memory device according to a related art; and

FIGS. 4 to 7 are cross-sectional diagrams for explaining a method of fabricating a flash memory device according to the present invention.

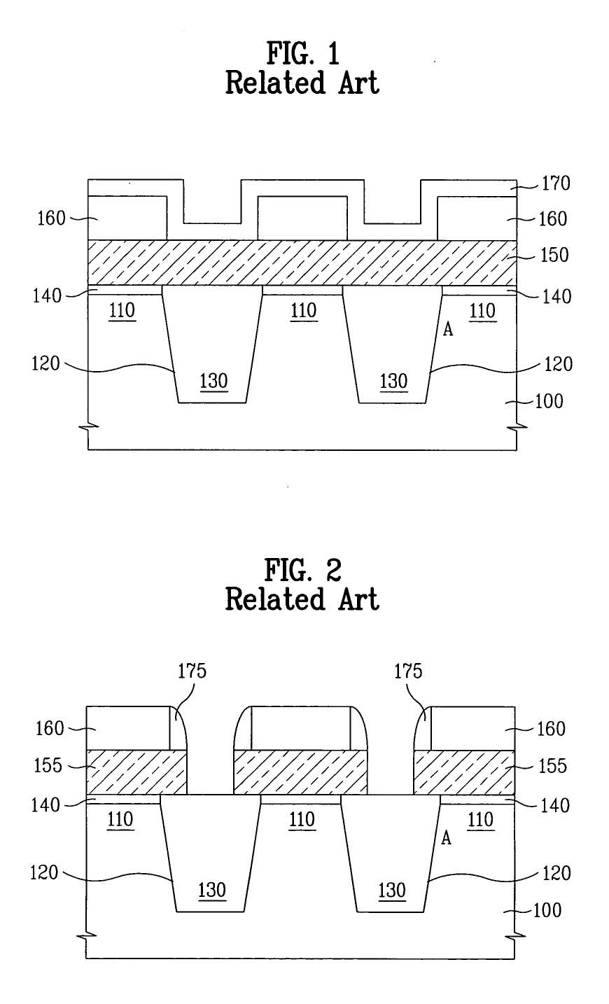

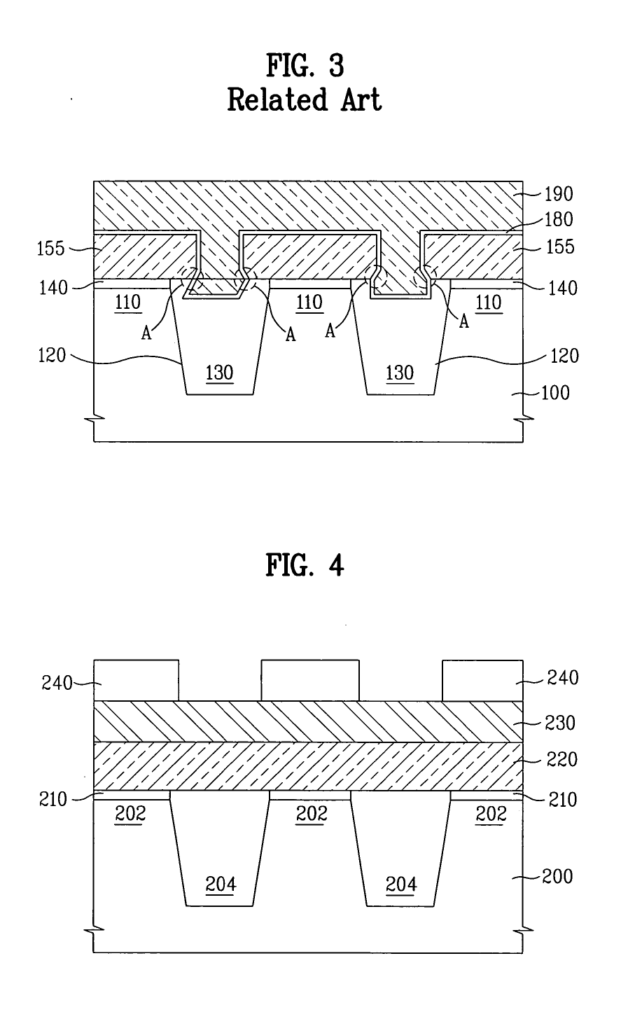

### DETAILED DESCRIPTION OF THE INVENTION

Reference will now be made in detail to the preferred embodiments of the present invention, examples of which are illustrated in the accompanying drawings. Wherever possible, the same reference numbers will be used throughout the drawings to refer to the same or like parts.

FIGS. 4 to 7 are cross-sectional diagrams for explaining a method of fabricating a flash memory device according to the present invention.

Referring to FIG. 4, a trench isolation layer 204 is formed in a device isolation area of a semiconductor substrate 200 by general trench isolation. In doing so, a trench is filled up with a filling insulating layer to form the trench isolation layer 204. And, a high density plasma oxide layer is used as the filing insulating layer. By the trench isolation layer 204, an active area 202 of the semiconductor substrate 200 is defined.

Subsequently, a tunnel oxide layer 210 is formed on the active area 202 of the semiconductor substrate 200.

A first conductor layer 220 for forming a floating gate is formed on the trench isolation layer 204 and the tunnel oxide layer 210.

An insulating layer 230 is formed on the first conductor layer 220, and a mask layer pattern 240, e.g., photoresist pattern 240, is formed on the insulating layer 230. In doing so, the photoresist pattern 240 has openings exposing portions of the insulating layer 230. And, the insulating layer 230 is formed of a plasma nitride layer to prevent undercut from occurring at the trench isolation layer 204 in removing the plasma nitride layer later. In case of forming the insulating layer 230 using the plasma nitride layer, a process temperature is about 350˜600° C.

Optionally, a buffer layer (not shown in the drawing) may be formed on the first conductor layer 220 prior to forming the insulating layer after formation of the first conductor layer 220. The buffer layer enables the first conductor layer 220 to be protected in etching to remove the insulating layer 230 later. And, an oxide layer 50˜500 Å thick can be used as the buffer layer. Alternatively, the buffer layer can be formed of one selected from the group consisting of PSG, BPSG, TEOS, and the like.

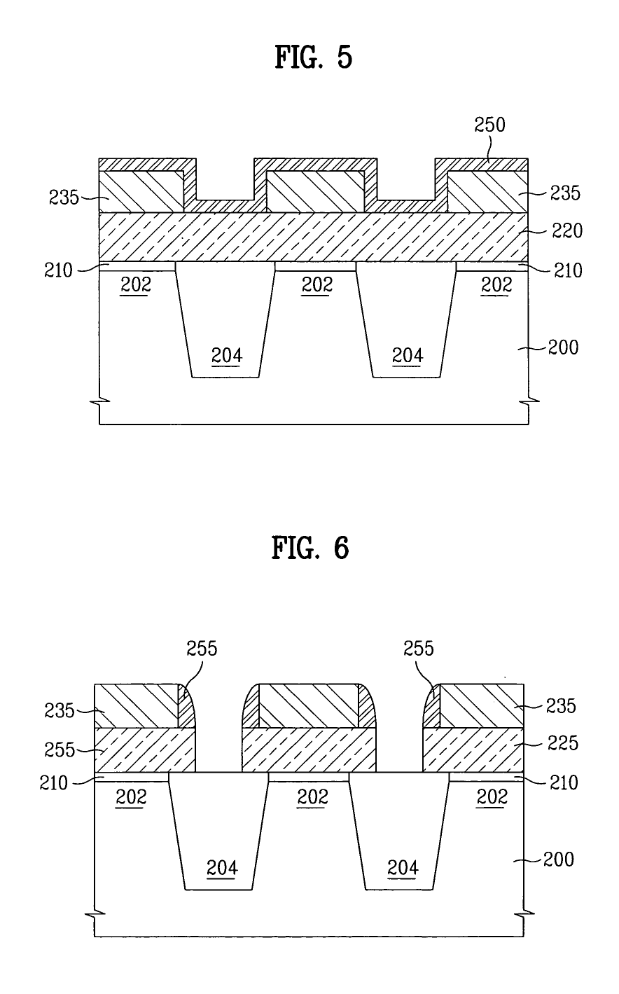

Referring to FIG. 5, the exposed portions of the insulating layer 230 in FIG. 4 are etched using the photoresist pattern 240 in FIG. 4 as an etch mask, whereby an insulating layer pattern 235 having openings respectively exposing portions of the first conductor layer 220 is formed. In case that the buffer layer is provided, the insulating layer pattern 235 exposes portions of the buffer layer.

Subsequently, a spacer insulating layer 250 is formed on the insulating layer pattern 235 and the exposed portions of the first conductor layer 220. The spacer insulating layer 250 is preferably formed of the same material of the insulating layer pattern 235, i.e., the plasma nitride layer. This is to remove the spacer insulating layer 250 and the insulating layer pattern 235 by one etch process later.

Referring to FIG. 6, the spacer insulating layer 250 is anisotropically etched to form a spacer 255 on a sidewall of the insulating layer pattern 235. In doing so, etchback is carried out on the spacer insulating layer 250.

And, the exposed portions of the first conductor layer 220 in FIG. 5 are etched using the spacer 255 and the insulating layer pattern 235 as an etch mask. Hence, a first conductor layer pattern 225 exposing a portion of the trench isolation layer 204 is formed. And, the first conductor layer pattern 225 will be used as a floating gate.

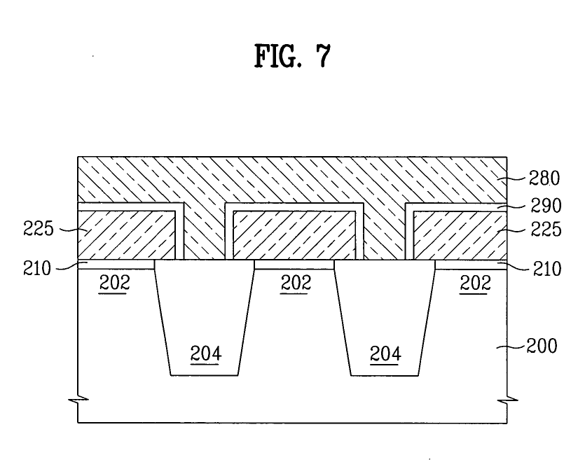

Referring to FIG. 7, the insulating layer pattern 235 in FIG. 6 and the spacer 255 in FIG. 6 are removed. In doing so, the insulating layer pattern 235 and spacer 255 formed of the plasma nitride layers are removed by wet etch using a H₃PO₄ solution at 130˜170° C. as an etchant. In this case, an etch selectivity between the insulating layer pattern 235 or spacer 255 and the trench isolation layer 204, i.e., the high density plasma oxide layer, is 70˜150:1. Hence, even if a portion of the trench isolation layer 204 is exposed in part while removing the insulating layer pattern 235 and the spacer 255 by the wet etch, the exposed portion of the trench isolation layer 204 is free from undercut or almost no undercut is generated from the exposed portion of the trench isolation layer 204.

After the insulating layer pattern 235 and the spacer 255 have been removed, a gate-to-gate insulating layer 290 is formed on the exposed portions of the first conductor layer pattern 225 and the trench isolation layer 204. In doing so, the gate-to-gate insulating layer 290 is formed of an ONO (oxide/nitride/oxide) layer.

And, a second conductor layer 280 for a control gate is formed on the gate-to-gate insulating layer 290. In doing so, the second conductor layer 280 is formed of polysilicon.

Thereafter, contacts, wires, and the like are further carried out to complete a flash memory device.

Accordingly, in the present invention, the coupling ratio is raised in a manner of shortening the interval between the floating gates using the spacer as the etch mask, whereby it is facilitated to fabricate the flash memory device having enhanced operational characteristics.

And, the present invention avoids the bridge occurrence between control and floating gates in a manner of suppressing the undercut generation from the trench isolation layer using high etch selectivity between the floating gate etch mask pattern or spacer and the trench isolation layer.

It will be apparent to those skilled in the art that various modifications and variations can be made in the present invention. Thus, it is intended that the present invention covets the modifications and variations of this invention provided they come within the scope of the appended claims and their equivalents.

1. A method of fabricating a flash memory device, comprising the steps of:
forming a trench isolation layer defining an active area of a semiconductor substrate;
forming a tunnel oxide layer on the active area of the semiconductor substrate;
forming a first conductor layer for a floating gate on the tunnel oxide layer and the trench isolation layer;
forming an insulating layer pattern on the first conductor layer with a prescribed layer having high etch selectivity with the trench isolation layer to expose a portion of the first conductor layer;
forming a spacer on a sidewall of the insulating layer pattern;
forming a first conductor layer pattern exposing a portion of the trench isolation layer by removing the exposed portion of the first conductor layer using the spacer as an etch mask;
removing the insulating layer pattern and the spacer;
forming a gate-to-gate insulating layer on the first conductor layer pattern and the trench isolation layer; and
forming a second conductor layer for a control gate on the gate-to-gate insulating layer.

2. The method of claim 1, wherein the trench isolation layer is formed of high density plasma oxide and wherein both of the insulating layer pattern and the spacer are formed of plasma nitride.

3. The method of claim 2, wherein the plasma nitride is deposited at 350˜600° C.

4. The method of claim 2, wherein the insulating layer pattern and the spacer are removed by wet etch using a H₃PO₄ solution as an etchant.

5. The method of claim 1, wherein the etch selectivity between the insulating pattern and the trench isolation layer is 70˜150:1.

6. The method of claim 1, wherein both of the first and second conductor layers are formed of polysilicon and wherein the gate-to-gate insulating layer is formed of a oxide/nitride/oxide layer.

7. The method of claim 1, further comprising the step of forming a buffer layer on the first conductor layer prior to forming the insulating layer pattern.

8. The method of claim 7, wherein the buffer layer is formed of an oxide layer 50˜500 Å thick.

9. The method of claim 7, wherein the buffer layer is formed of one selected from the group consisting of PSG, BPSG, and TEOS.
